(19) United States
(12) Patent Application Publication
(10) Pub. No.: US 2026/0067197 A1
(43) Pub. Date: Mar. 5, 2026

(54) METHODS, SYSTEMS, AND COMPUTER READABLE MEDIA FOR DATA CENTER SWITCHING NETWORK PATH EMULATION IN AN ELECTRONICS DESIGN AUTOMATION (EDA) ENVIRONMENT

(71) Applicant: Keysight Technologies, Inc., Santa Rosa, CA (US)

(72) Inventors: Christian Paul Sommers, Bangor, CA (US); Lucian Mogosanu, Bucharest (RO)

(21) Appl. No.: 18/820,969

(22) Filed: Aug. 30, 2024

(30) Foreign Application Priority Data
Aug. 29, 2024 (RO) A 2024 00499

(51) Int. Cl. H04L 43/20; G06F 30/20; H04L 41/14; H04L 41/147; H04L 41/16; H04L 43/50

(52) U.S. Cl. CPC H04L 43/20; G06F 30/20; H04L 41/145; H04L 41/147; H04L 41/16; H04L 43/50

(57) ABSTRACT

A method for data center switching fabric path emulation in an electronics design automation (EDA) environment includes generating emulated data center traffic. The method further includes, at a path emulation element, modifying the emulated data center traffic to emulate passing of the emulated data center traffic through a data center switching fabric. The method further includes outputting, by the path emulation element, the modified emulated data center traffic to an EDA emulator emulating an electronics design under test. The method further includes receiving and storing a response of electronics design under test to the modified emulated data center traffic.

### PRIORITY CLAIM

This application claims the priority benefit of Romanian Patent Application No. (Serial No. not yet assigned), filed Aug. 29, 2024, and entitled, “METHODS, SYSTEMS, AND COMPUTER READABLE MEDIA FOR DATA CENTER SWITCHING NETWORK PATH EMULATION IN AN ELECTRONICS DESIGN AUTOMATION (EDA) ENVIRONMENT”, the disclosure of which is incorporated herein by reference in its entirety.

### TECHNICAL FIELD

The subject matter described herein relates to EDA testing. More particularly, the subject matter described herein relates to methods, systems, and computer readable media for data center switching network path emulation in an EDA environment.

### BACKGROUND

Electronics design automation refers to the process of designing integrated circuits using software and firmware tools, such as logic design, synthesis, and verification tools, that are used to design and test a proposed integrated circuit before the design is committed to hardware. One type of tool used in EDA is referred to as an EDA emulator. An EDA emulator emulates a hardware design so that the functionality and performance of the design can be tested prior to finalizing the design in hardware. In some cases, an EDA emulator consists of two parts: a transactor and a design under test (DUT). The emulator is a system that is capable of loading and running ASIC designs in a form that resembles the final tapeout. The ASIC design running inside the emulator is called a design under test (DUT). The transactor is a component of the emulator that simulates an external I/O entity. This entity is usually connected to the DUT through a standard interface (e.g., PCIe or Ethernet). The DUT implements its own I/O logic, such as PCIe or Ethernet logic. The transactor may also simulate certain aspects of the external interface, such as L1 and L2 Ethernet logic. The transaction may also simulate characteristics of a bus or a wire that connects the external device and the DUT

The DUT is the hardware definition language (HDL) implementation of the design being evaluated. For example, in computer networking, the DUT may be an implementation of a network chip, such as an Ethernet chip.

It is desirable to test an emulated electronics design under test under conditions that mimic the conditions that the design being evaluated will experience in operation. For example, if the emulated electronics design under test is a data center switching application specific integrated circuit (ASIC), then it may be desirable to generate and send emulated data center traffic to the design and monitor the performance of the design. The emulated data center traffic should include emulated impairments, such as delays and dropped packets, that mimic the impairments that will be experienced by real traffic traversing a data center switching fabric. In addition to making the emulated traffic appear realistic, another challenge or goal in emulating data center switching fabric traffic impairments is that the EDA emulator and the data center traffic emulation system may operate in different timing domains. For example, when data center traffic generation system is loosely coupled to the EDA emulator through an application programming interface (API)-based interface, the two systems may operate in different timing domains. Operating such loosely coupled system enables test developed for the pre-silicon environment to be re-used for testing chips in the post-silicon environment. When the two systems operate in different timing domains, any data center traffic emulation system must account for the difference in timing domains to ensure that the desired impairments are properly emulated. Yet another challenge in emulating data center switching fabric traffic impairments is where and how to perform the network path emulation.

In light of these and other difficulties, there exists a need for improved methods, systems, and computer readable media for data center switching network path emulation in an EDA environment.

### SUMMARY

A method for data center switching fabric path emulation in an electronics design automation (EDA) environment includes generating emulated data center traffic. The method further includes, at a path emulation element, modifying the emulated data center traffic to emulate passing of the emulated data center traffic through a data center switching fabric. The method further includes outputting, by the path emulation element, the modified emulated data center traffic to an EDA emulator emulating an electronics design under test. The method further includes receiving and storing a response of electronics design under test to the modified emulated data center traffic.

According to another aspect of the subject matter described herein, generating emulated data center traffic includes generating emulated traffic of a data center processing an artificial intelligence/machine learning (AI/ML) workload.

According to another aspect of the subject matter described herein, modifying the emulated data center traffic includes adding, to the emulated data center traffic, a packet timing parameter that controls a time or spacing between emulated data packets provided by a transactor of the EDA emulator to the electronics design under test.

According to another aspect of the subject matter described herein, the path emulation element is implemented as an inline device between a test traffic generator that generates the emulated data center traffic and the EDA emulator.

According to another aspect of the subject matter described herein, the path emulation element is connected between virtual interfaces between the test traffic generator and the EDA emulator.

According to another aspect of the subject matter described herein, the path emulation element is implemented using a network device (netdev), an emulated switch, or a filter connected between the virtual interfaces.

According to another aspect of the subject matter described herein, the path emulation element is located in a tunnel between the test traffic generator and the EDA emulator.

According to another aspect of the subject matter described herein, the path emulation element is configured to propagate indications of backpressure and communicate emulator timing information from the EDA emulator to the test traffic generator.

According to another aspect of the subject matter described herein, the path emulation element is integrated within a test traffic generator that generates the emulated data center traffic.

According to another aspect of the subject matter described herein, the path emulation element is implemented as a component of a transactor of the EDA emulator.

According to another aspect of the subject matter described herein, a system for data center switching fabric path emulation in an electronics design automation (EDA) environment is provided. The system includes at least one processor and a memory. The system further includes a test traffic generator for generating emulated data center traffic. The system further includes a path emulation element implemented by the at least one processor for modifying the emulated data center traffic to emulate passing of the emulated data center traffic through a data center switching fabric and outputting the modified emulated data center traffic to an EDA emulator emulating an electronics design under test. The system further includes a test results database for receiving and storing a response of electronics design under test to the modified emulated data center traffic.

According to another aspect of the subject matter described herein, the test traffic generator is configured to generate emulated traffic of a data center processing an artificial intelligence/machine learning (AI/ML) workload.

According to another aspect of the subject matter described herein, the path emulation element is configured to modify the emulated data center traffic by adding, to the emulated data center traffic, a packet timing parameter that controls a time or spacing between emulated data packets provided by a transactor of the EDA emulator to the electronics design under test.

According to another aspect of the subject matter described herein, a non-transitory computer readable medium having stored thereon executable instructions that when executed by a processor of a computer control the computer to perform steps is provided. The steps include generating emulated data center traffic. The steps further include at a path emulation element, modifying the emulated data center traffic to emulate passing of the emulated data center traffic through a data center switching fabric. The steps further include outputting, by the path emulation element, the modified emulated data center traffic to an electronics design automation (EDA) emulator emulating an electronics design under test. The steps further include receiving and storing a response of electronics design under test to the modified emulated data center traffic.

The subject matter described herein can be implemented in software in combination with hardware and/or firmware. For example, the subject matter described herein can be implemented in software executed by a processor. In one exemplary implementation, the subject matter described herein can be implemented using a non-transitory computer readable medium having stored thereon computer executable instructions that when executed by the processor of a computer control the computer to perform steps. Exemplary computer readable media suitable for implementing the subject matter described herein include non-transitory computer-readable media, such as disk memory devices, chip memory devices, programmable logic devices, and application specific integrated circuits. In addition, a computer readable medium that implements the subject matter described herein may be located on a single device or computing platform or may be distributed across multiple devices or computing platforms.

### BRIEF DESCRIPTION OF THE DRAWINGS

Exemplary implementations of the subject matter described herein will now be explained with reference to the accompanying drawings, of which:

FIG. 1 is a block diagram illustrating a test traffic generation system in which a path emulation element is implemented as an inline device located between the test traffic generators and the EDA emulator;

FIG. 2 is a block diagram illustrating an example in which the path emulation element is integrated with emulated traffic generators;

FIG. 3 is a block diagram illustrating three possible locations for implementing a path emulation element;

FIG. 4 is a block diagram illustrating in more detail an implementation of path emulation via inline traffic modification;

FIG. 5 is a block diagram illustrating the use of Linux network devices (netdevs) to insert a path emulation element inline between traffic generators and an emulated electronics design under test;

FIG. 6 is a block diagram illustrating inline path emulation where the emulated switches are implemented using P4 behavioral model version 2 (bmv2) over sockets;

FIG. 7 is a block diagram illustrating the use of dataplane developers kit (DPDK) virtio netdevs to insert a path emulation element inline between traffic generators and an emulated electronics design under test;

FIG. 8 is a block diagram illustrating the use of open virtual switch (OVS) or P4 to insert a path emulation element inline using vhost-user (virtio) netdevs;

FIG. 9 is a block diagram illustrating the use of Linux traffic control (tc) to insert a path emulation element inline between traffic generators and an emulated electronics design under test;

FIG. 10 is a block diagram illustrating the use of tunneling to insert a path emulation element inline between traffic generators and an emulated electronics design under test;

FIG. 11 is a block diagram illustrating the use of Netlink for userspace inline path emulation elements;

FIG. 12 is a block diagram illustrating methods for communicating path emulation metadata as part of a data packet;

FIG. 13 is a block diagram illustrating methods for communicating path emulation metadata as a control packet;

FIG. 14 is a block diagram illustrating handling of backpressure when testing an EDA design under test using an inline path emulation element;

FIG. 15 is a block diagram illustrating communication of clock information from an EDA emulator to a traffic generator via a path emulation element; and

FIG. 16 is a flow chart illustrating an exemplary process for data center switching network patent emulation in an EDA environment.

### DETAILED DESCRIPTION

The subject matter described herein is intended for use with a DUT implemented by an EDA emulator, which is configured to test a pre-silicon chip design. A pre-silicon chip design is an HDL-implemented version of a chip design that needs to be tested for functionality and performance before committing the design to hardware. An EDA emulator executes the chip emulation using a clock local to the emulator. The clock local to the emulator provides a timing domain that is referred to herein as the EDA emulator time domain.

As stated above, one key need of EDA emulation platforms is the ability to test a pre-silicon chip design with realistic network traffic associated with high-performance distributed processing tasks, such as artificial intelligence/machine learning (AI/ML) workload tasks. Such testing requires coordination between test traffic generators, AI/ML workload simulators, and the EDA emulator.

The subject matter described herein achieves robust testing of an electronics design under test by using network test system components to handle the complexities involved in generating high-fidelity packet traffic that is representative of AI/ML workload processing in a realistic/complex distributed computing environment (i.e., environments that include complex switching fabrics/topologies, complex congestion control mechanisms, realistic impairment mechanisms, etc.) and further allows EDA platform users to easily manipulate AI/ML workload configurations (e.g., collective communication strategies, distributed processor models/types, switching fabric types and attributes, etc.).

One challenge in creating a network test system that is capable of performing the functions described above relates to how to address/handle the differences between network test system clocking/time domain and the EDA emulator clocking/time domain when emulating packet impairments that would occur in a data center switching environment.

The subject matter described herein includes a path emulation element that may utilize distributed processing task specification information (e.g., from a Chakra execution trace/graph, etc.), as well as distributed computing environment information (e.g., distributed processor types, capabilities, topology, switching fabric attributes, load balancing configuration, etc.) along with EDA emulator clock/time information in order to compute a path emulation timing parameter value, such as an inter-frame gap (IFG), that is associated with some or all test packets generated by the network test system. In one example, the path emulation element may include the path emulation timing parameter in a test packet (e.g., as metadata in a designated packet header field, etc.). In another example, the path emulation element may communicate the path emulation timing parameter to the EDA emulator separately from the emulated network traffic, e.g., in a control channel that is implemented using packets or local or remote shared memory access.

The transactor of the EDA emulator receives the path emulation timing parameter from the path emulation element and uses the path emulation timing parameter to determine the time or spacing between test packets presented to the electronics design under test that is being emulated on the platform.

In addition to generating and including a path emulation timing parameter value in a test packet as a technique for representing timing conditions/effects in an emulated distributed computing environment, the path emulation element may manipulate test packet contents in the course of emulating various distributed computing environment paths/network conditions. For example, the path emulation element may set an explicit congestion notification (ECN) flag in order to mimic congestion in fabric switches within the emulated environment.

In another exemplary use case, the test system may generate and transmit a congestion notification packet (CNP) packet from an emulated network interface card (NIC) to simulate responder behavior in a remote direct memory access (RDMA) over converged Ethernet version 2 (RoCEv2) environment. In another exemplary use case, the test system may perform packet trimming—trim a test packet in an emulated “switch” to simulate/test network data center protocol (NDP) protocol. In other contemplated use cases, the test system is adapted to mimic other transport-layer behaviors, such as load-balancing within the switching fabric, and may simulate equal cost multipath (ECMP) routing or spraying across ports in a multi-tier scale-out fabric, including polarization.

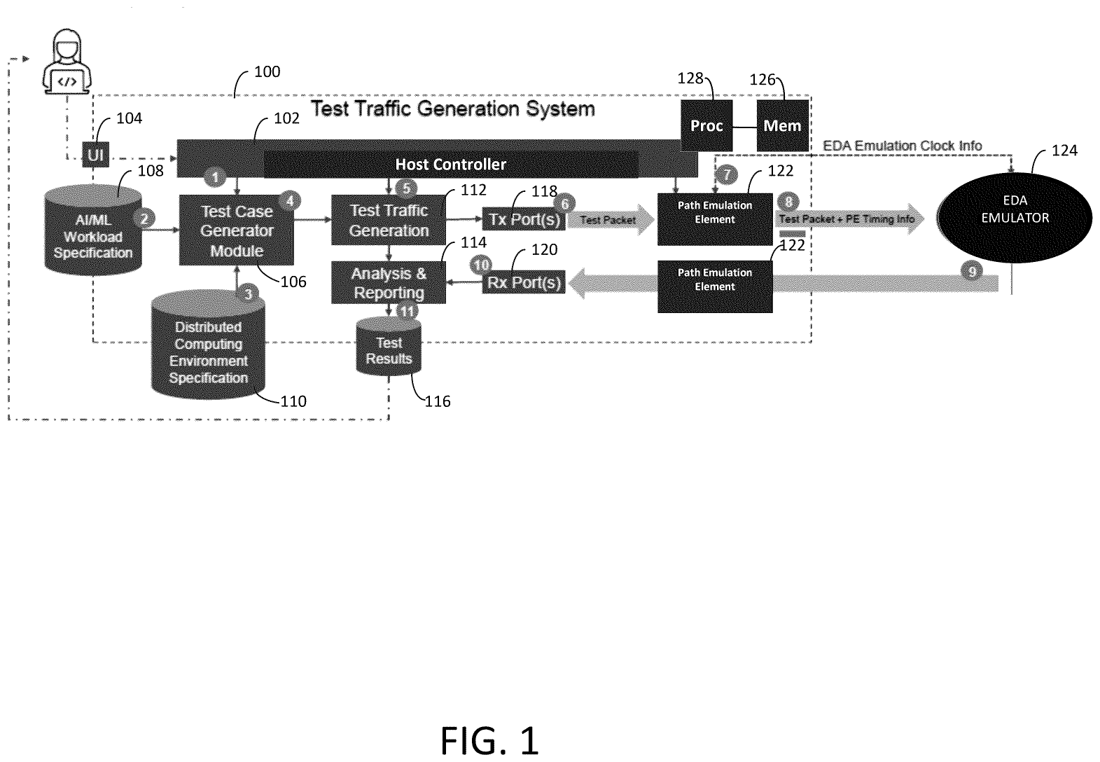

In one implementation of the subject matter described herein, the path emulation element is an inline device located between the test traffic generator and the EDA emulator. FIG. 1 illustrates an example of a test traffic generation system in which the path emulation element is implemented as an inline device located between the test traffic generators and the EDA emulator. Referring to FIG. 1, test traffic generation system 100 includes a host controller 102 that controls the overall operation of test traffic generation system 100. A user interface 104 allows a user to configure test parameters. A test case generator module 106 receives an AI/ML workload specification 108 and a distributed computing environment specification 110 and outputs a test case to be used by test traffic generator 112 in generating test traffic. Traffic generated by test traffic generator 112 and traffic received from an EDA emulator 124 are provided to an analysis and reporting module 114 that generates reports and stores the reports in a test results database 116. Test traffic generation system 100 further includes transmit ports 118 for transmitting traffic to the device under test and receive ports 120 for receiving traffic from the device under test.

In FIG. 1, ingress and egress path emulation elements 122 are located in line between test traffic generator 112 and EDA emulator 124 that emulates an electronics design under test. Path emulation element 122 on the ingress side of EDA emulator 124 modifies test traffic generated by test traffic generator 112 to make the test traffic appear as the test traffic has passed through one or more paths of a data center switching fabric. In one example, path emulation element 122 adds timing parameter values to the test traffic that cause the transactor of the EDA emulator 124 to alter the timing at which packets are provided to the electronics design under test. Path emulation element 122 on the ingress side of EDA emulator 124 may also add impairments to the test traffic generated by test traffic generator 112 before providing the test traffic to EDA emulator 124. EDA emulator 124 emulates an electronics design, such as a chip design under test. Traffic output from EDA emulator 124 is provided to test system 100 via receive ports 120. Path emulation element 122 on the egress side of EDA emulator 124 may receive traffic from EDA emulator 124 and provide the traffic to test system for analysis. The components of test traffic generation system 100 may be implemented using computer executable instructions that are stored in a memory 126 and executed by a processor 128.

Referring to the numbered steps in FIG. 1, in step 1, a test system user selects/provides/provisions and initiates execution of a test by test traffic generation system 100 for generating test traffic and providing the test traffic to EDA emulator 124. In step 2, distributed computing workload specification 108, which may be a Chakra execution trace/graph associated with an AI/ML model training task is selected for emulation and provided as an input to test case generator module 106. In step 3, distributed computing environment specification 110 is selected or provisioned and provided as a second input to test case generator module 106. Distributed computing environment specification 110 may include processor types/models (e.g., graphics processing units (GPUs)), processor capabilities, processor interconnection topology, collective communication configuration, switching fabric topology, switching resource capabilities and configurations, etc. In step 4, test case generator module 106 processes distributed computing workload specification 108 and the distributed computing environment specification 110 (and potentially other configuration settings and parameter values, etc.) and generates an associated test case definition that can be interpreted and executed by other components of the network test system (e.g., traffic engines, etc.).

In step 5, based on the test case definition, host controller 102 configures one or more test traffic generators 112 to generate a sequence of test packets for testing a chip design under test (CDUT) as emulated by EDA emulator 124. In step 6, the one or more test traffic generators 112 generate a sequence of test packets that are forwarded to test system transmit port 118 and received by path emulation element 122.

Path emulation element 122 on the ingress side of EDA emulator 124 receives the emulated data center traffic. In step 7, path emulation element 122 on the ingress side of EDA emulator 124 requests and/or receives EDA platform clock/timing information and uses this timing information, along with test case definition information (e.g., Chakra execution trace/graph information, distributed processor configuration/topology information, etc.) to compute a path emulation timing parameter value that is associated with one or more of the test packets. In one example, the path emulation timing parameter value is incorporated into one or more of the test packets (e.g., as metadata in an unused packet field/parameter, etc. The path emulation timing parameter value may be interpreted by the transactor of EDA emulator 124 as a relative time delay, i.e., an inter-frame gap, that should be applied to the test packet with respect to the prior test packet in a sequence of test packets. In another example, the path emulation timing parameter value may be interpreted by the transactor of EDA emulator 124 as the absolute time (with respect to the EDA platform clock) that the test packet should be delivered/presented to the electronics design under test. For example, the path emulation timing parameter may be an inter-frame gap that when read by EDA emulator 124 causes EDA emulator 124 to wait a specified number of clock ticks or bytes before providing the packet to the electronics design under test. In step 8, path emulation element 122 on the ingress side of EDA emulator 124 transmits the one or more modified test packets to EDA emulator 124.

The transactor of EDA emulator 124 provides the test packet to the emulated electronics design under test using the timing specified by the timing parameter value. The emulated electronics design under test receives the test packet, switches the packet, and, in step 9, transmits the packet to test system 100 via path emulation element 122 on the egress side of EDA emulator 124. In step 10, the switched packet or other output of the electronics design under test is provided to analysis and reporting module 114, which generates reports and stores the reports in test results database 116.

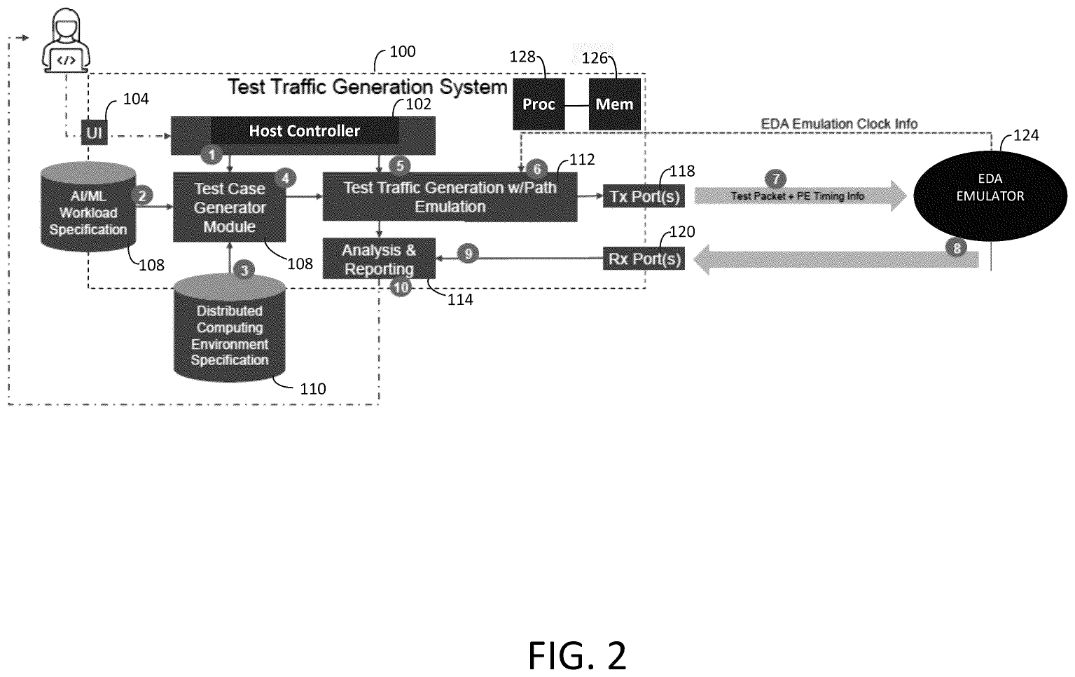

In the example illustrated in FIG. 1, path emulation element 122 is implemented as an inline device between test traffic generator 112 and EDA emulator 124. In an alternate implementation, path emulation element 122 may be integrated with test traffic generator 112. FIG. 2 illustrates such an example. The components in FIG. 2 are the same as those in FIG. 1 except that path emulation element 122 is integrated with test traffic generator 112 and the ingress and egress side path emulation elements are combined and shown as a single path emulation element 122. In FIG. 2, steps 1-5 are the same is those described above with respect to FIG. 1. In step 6, test traffic generator 112 generates the emulated data center traffic. Path emulation element 122 modifies at least some of the emulated data center packets generated by test traffic generator 112 to include the above-described timing parameter values, which control the timing at which the transactor of EDA emulator 124 provides the packet to the electronics design under test. Path emulation element 122 may also add impairments to the emulated data center traffic, such as delays, jitter, packet drops, etc.

In step 7, path emulation element 122 provides the modified emulated data center packets to EDA emulator 124. EDA emulator 124 provides the modified emulated data center packets to the electronics design under test. In step 8, the electronics design under test produces output and provides the output to test traffic generation system via receive ports 120. In step 9, receive ports 120 provide the output to analysis and reporting module 114. In step 10, analysis and reporting module 114 generates one or more reports based on the processing of the emulated data center traffic uh the electronics design under test.

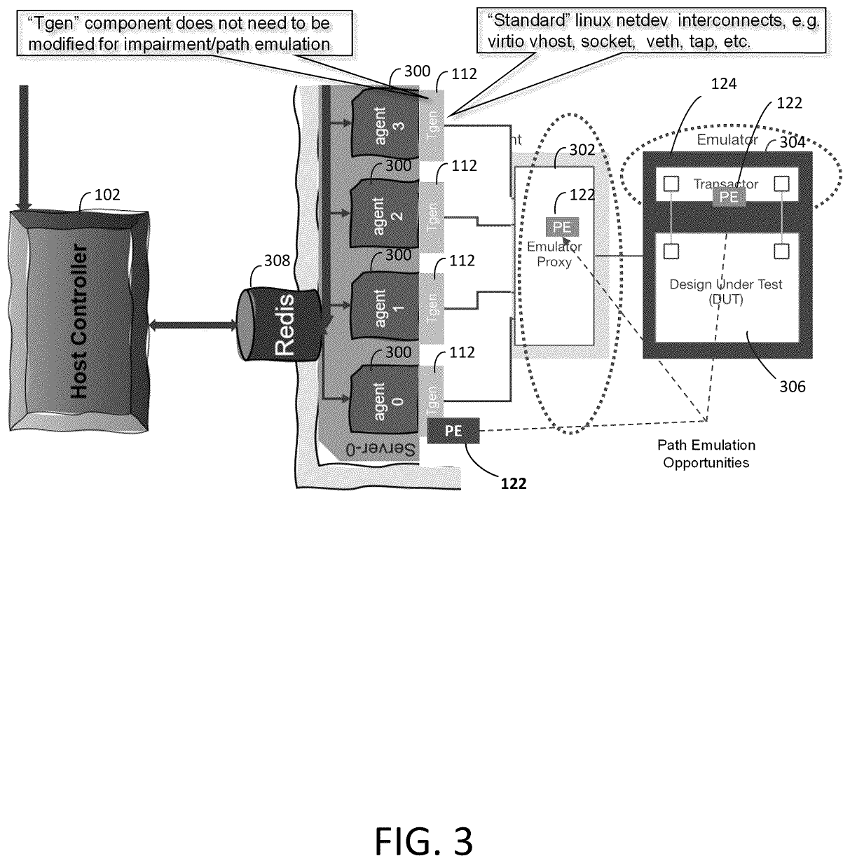

FIG. 3 is a block diagram illustrating three possible locations for implementing a path emulation element. Referring to FIG. 3, a plurality of agents 300 emulate data center processing elements, such as graphics processing units (GPUs). Traffic generators 112 packetize and send emulated datacenter workload traffic from agents 300 to EDA emulator 124. In one inline example illustrated in FIG. 3, path emulation element 122 can be implemented on an emulator proxy 302 located between traffic generators 112 and a transactor 304, which is a component of EDA emulator 124. In the other inline example illustrated in FIG. 3, path emulation element 122 is implemented as a component of transactor 304. Transactor 304 is the component of EDA emulator 124 that physically communicates data to and receives data from electronics design under test 306. In the third example illustrated in FIG. 3, path emulation element 122 is implemented as a component of each traffic generator 112, which is the same location described above with respect to FIG. 2. For simplicity of illustration, only a traffic generator 112 is shown with an integrated path emulation element 122. In one example, host controller 102 communicates with other components of the test traffic generation system via remote dictionary server (Redis) database interface 308.

Path emulation element 122 may emulate data center switches, impairment devices, or both. Path emulation element 122 may be controllable by controller 102 to modify traffic inline to emulate unidirectional or bidirectional network paths. The emulated network paths may be point-to-point links or paths through complex data center fabrics. Providing an inline emulator path as illustrated in FIG. 3 facilitates path emulation at different protocol layers.

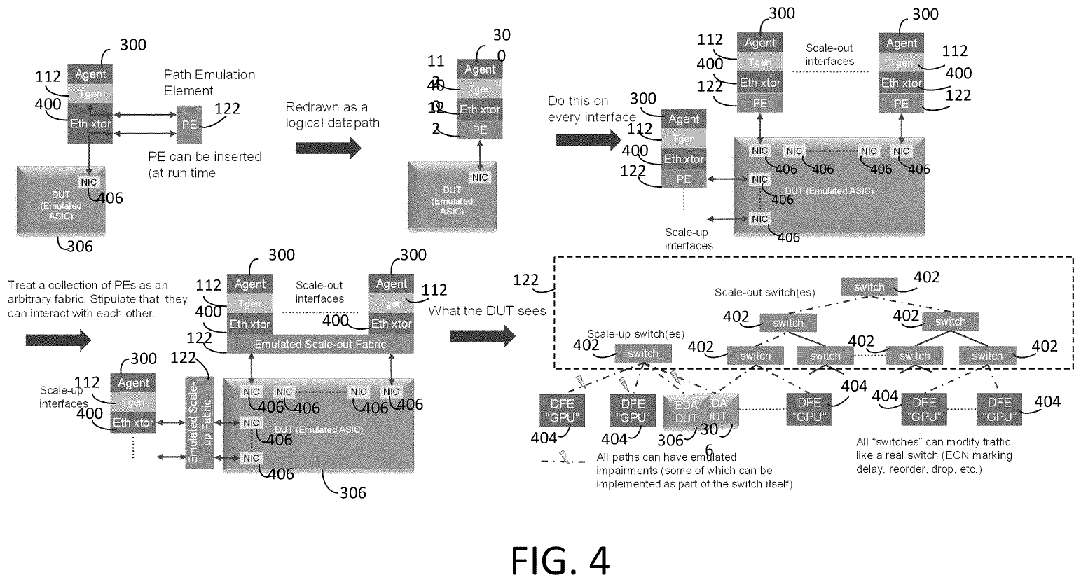

FIG. 4 is a block diagram illustrating in more detail an implementation of path emulation via inline traffic modification. In FIG. 4, emulator proxy 302 and transactor 304 are combined into a single element and illustrated as Eth xtor 400, recognizing that the transactor is conventionally located in EDA emulator 124. The location of Eth xtor 400 is shown externally to EDA emulator 124 in the drawings to convey its logical relationship to the path emulation performed by path emulation element 122. Path emulation element 122 bidirectionally switches and/or impairs data packets transmitted between traffic generators 112 and electronics design under test 306. In the illustrated example, path emulation element 122 emulates scale-up and scale out switching fabrics, which include plural emulated switches 402. Agents 300 emulate data center GPUs 404. Each emulated switch 402 is capable of modifying emulated traffic inline to include impairments, such as explicit congestion notification (ECN) markings, delay, packet drops, packet reordering, etc. In the example illustrated in FIG. 4, the combination of agent 300, traffic generator 112, Eth xtor 400, and path emulation element 122 is replicated for each network interface card (NIC) or traffic port 406 of electronics design under test 306 so that electronics design under test 306 sees itself as being connected to a real data center switching fabric that is in the process of switching data relating to an AI/ML workload.

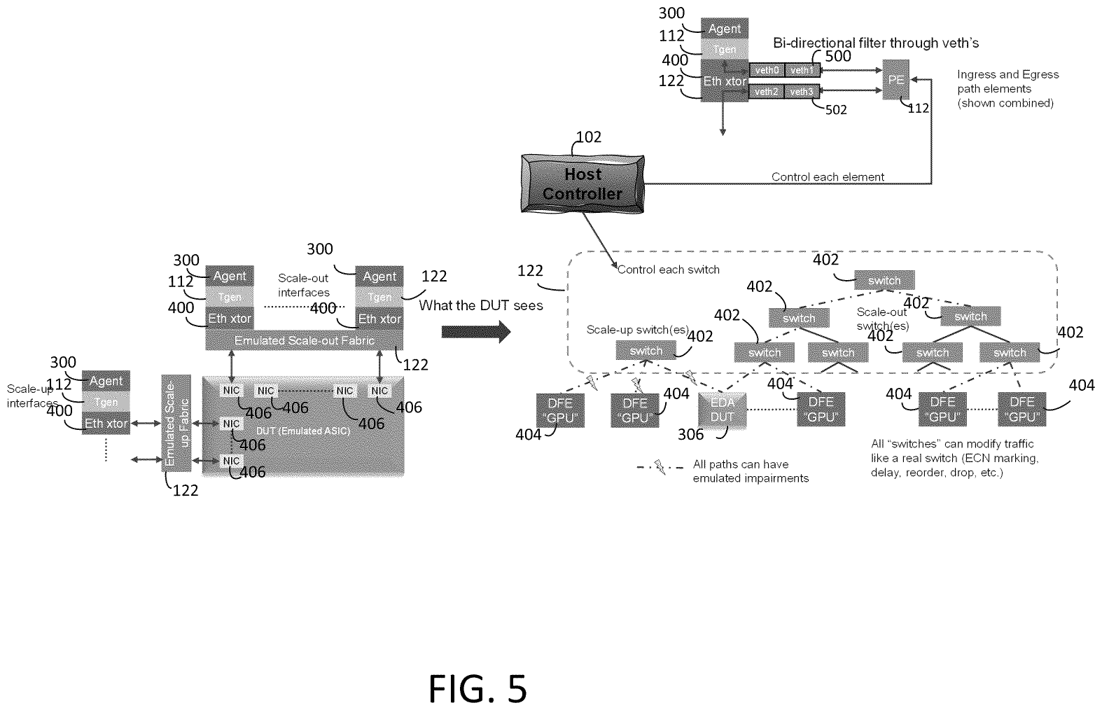

In one example, path emulation element 122 may be inserted inline by binding between a pair of Linux network devices (netdevs), such as virtual Ethernet (veth) interface pairs, taps, vhosts, etc. FIG. 5 is a block diagram illustrating the use of Linux network devices to insert path emulation element 122 inline between traffic generators 112 and electronics design under test 306. In FIG. 5, Ethernet transactor 400 is provided with a pair of Linux netdevs, which in the illustrated example are veth interfaces 500 and 502. Path emulation element 122 inserts itself inline between virtual ethernet interfaces 500 and 502 by binding to these interfaces. The binding and insertion can be implemented as a runtime option (e.g., via a runtime mode configuration, an environment variable, etc.). This allows path emulation element 122 to be implemented using arbitrary networking applications, such as open Vswitch (OVS), a custom P4 switch, an enhanced Berkley packet filter (eBPF), a DPDK soft switch, or custom program to intercept, modify, and switch emulated data center traffic.

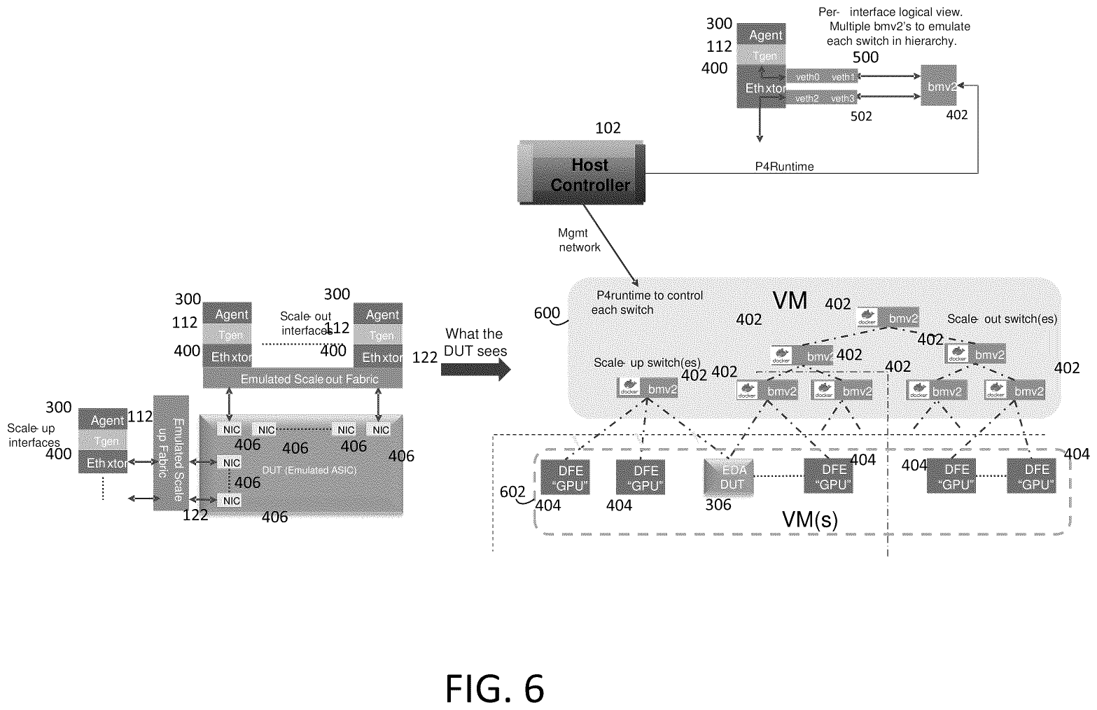

The data center switches emulated by path emulation elements 122 may be implemented using any suitable switch modeling technology. In one example, the emulated switches may be implemented using P4 bmv2 over sockets. FIG. 6 is a block diagram illustrating inline path emulation where the emulated switches are implemented using P4 bmv2 over sockets. Referring to FIG. 6, each emulated switch 402 comprises a P4 bmv2 switch. Emulated switches 402 can be controlled using P4 runtime controls. In the illustrated example, emulated switches 402 run in one virtual machine (VM) 600, and emulated GPUs 404 run in a separate VM 602. In an alternate implementation, emulated switches 402 and emulated GPUs 404 can run in the same VM. Multiple VMs can be used to scale the size of the emulated switching fabric. In a multi-VM environment, fabric connections may be routed between hypervisors. Inter-switch connections between emulated switches may use host networking within the VM, such as Linux bridging, to communicate with each other.

Each emulated switch 402 implements switching and/or impairment of emulated data center workload traffic. Each emulated switch 402 may run in a container. Each emulated switch 402 may be connected to a pair of virtual Ethernet interfaces, such as virtual Ethernet interfaces 500 and 502.

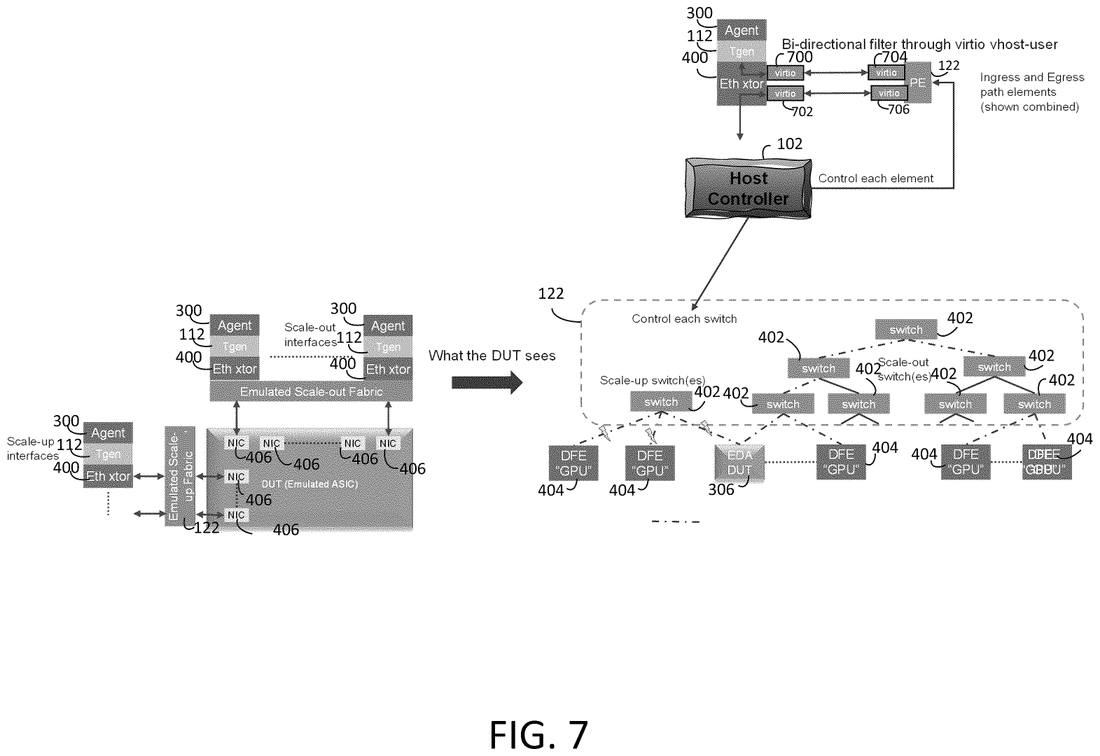

In another example, path emulation elements 122 may be inserted inline between traffic generators and the emulated electronic design under test using DPDK netdevs, such as virtio netdevs. FIG. 7 is a block diagram illustrating the use of DPDK virtio netdevs to insert a path emulation element inline between traffic generators and an emulated electronics design under test. In FIG. 7, a pair of virtio NICS 700 and 702 is implemented on ethernet transactor 400, and a corresponding pair of virtio NICs 704 and 706 is implemented on path emulation element 122. Path emulation element 122 can insert itself inline by binding to virtio interfaces 700 and 702. One benefit to using virtio to insert path emulation element 122 is the virtio interfaces preserve the EDA metadata in the cb[48] structure. In the example illustrated in FIG. 7, each emulated switch 402 can be a vhost-capable switch, such as an OVS switch or P4-based switch.

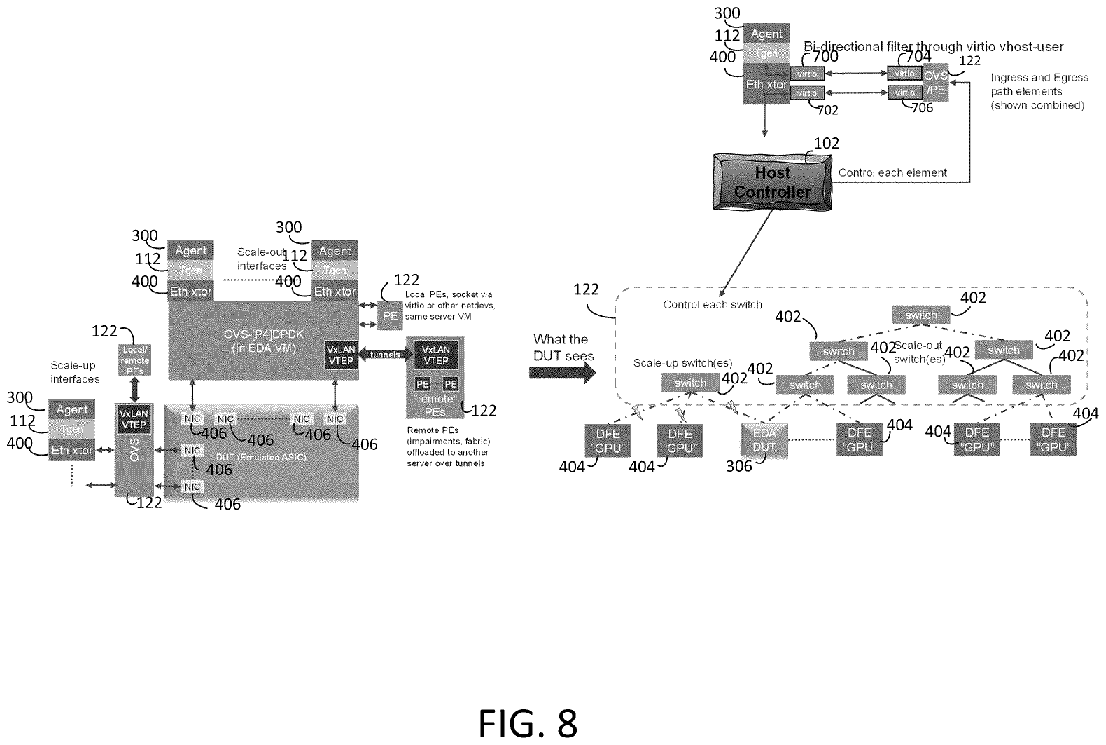

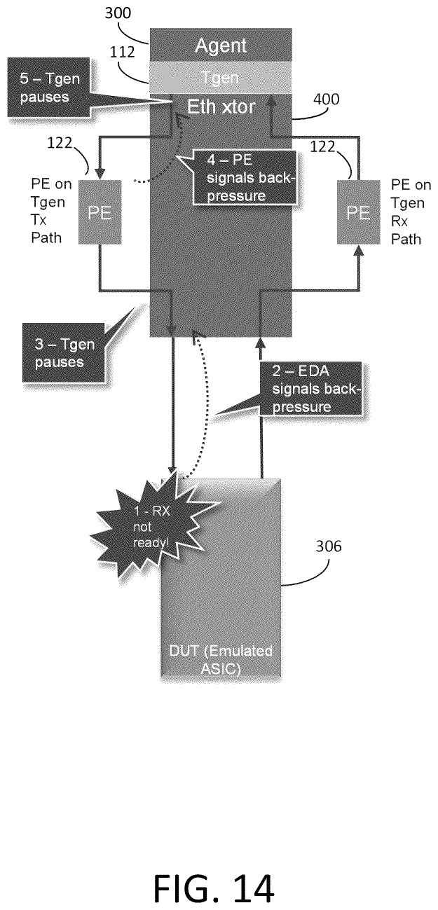

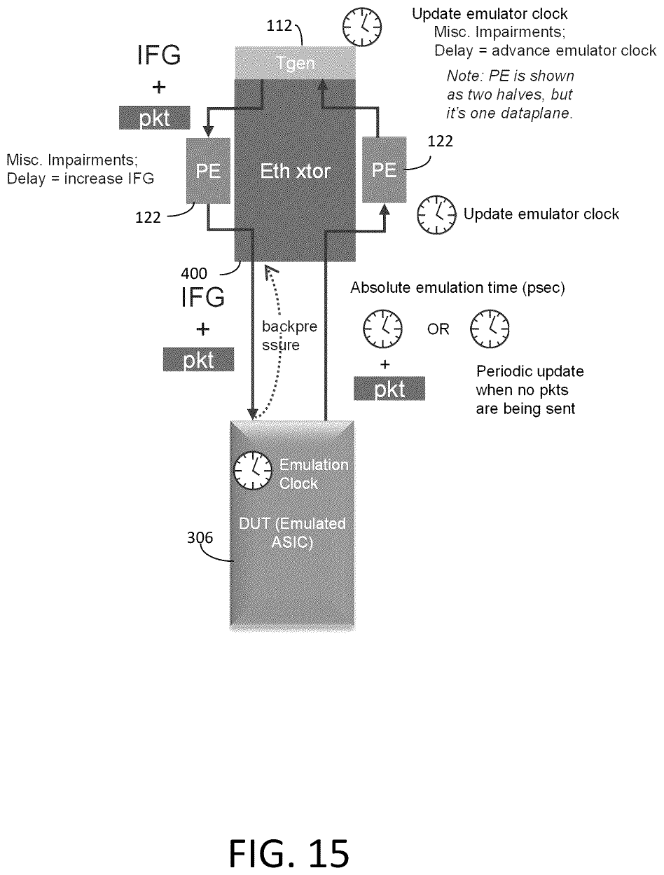

In one example, each emulated switch 402 can be a P4-DPDK switch running a program to implement the desired switching and/or impairment. FIG. 8 illustrates the use of OVS or P4 to insert a path emulation element inline using vhost-user (virtio) netdevs. Referring to FIG. 8, an OVS path emulation element 122 is inserted inline between virtio interfaces 700 and 702 of Eth xtor 400. OVS path emulation element 122 may include ingress and egress virtio interfaces 704 and 706. OVS path emulation element 122 can insert itself inline by binding to virtio interfaces 700 and 702. OVS can be extended to perform sk_buff metadata-to-packet bridging to allow sending traffic and metadata into external processes to perform path emulation or impairments, even remotely using VxLAN or other tunnels. OVS becomes a packet broker/bridge of sorts. To implement the design in FIG. 8, OVS path emulation element 122 may be modified to use the EDA clock and handle backpressure. EDA clock and backpressure handling will be described below with respect to FIGS. 14 and 15.

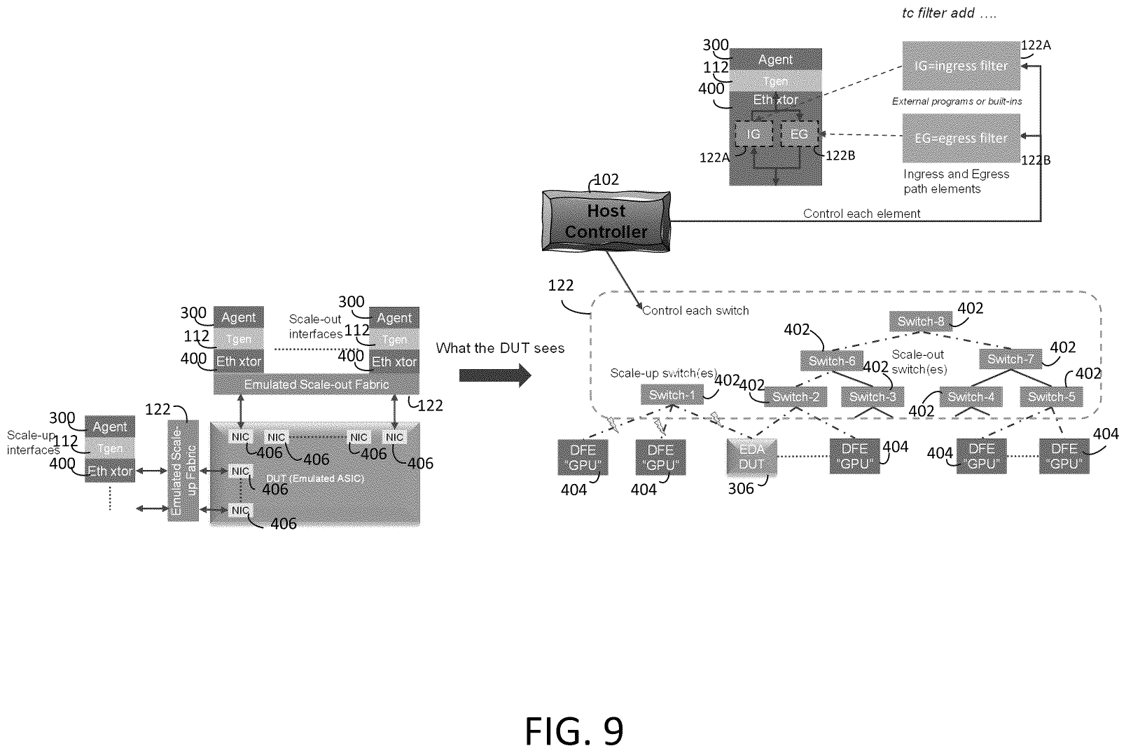

FIG. 9 is a block diagram illustrating the use of Linux tc to insert a path emulation element inline between traffic generators and an emulated electronics design under test. In FIG. 9, path emulation element 122 is implemented as an ingress path emulation element 122A and an egress path emulation element 122B inserted as inline filters using Linux tc. In the illustrated example, ingress path emulation element 122A and path emulation element gateway 122B are implemented as components or filters within Eth xtor 400 between traffic generators 112 and electronics design under test 306. Ingress gateway 122A and egress gateway 122B may utilize standard Linux tc built-ins or may use custom programming defined in eBPF, P4, or other programming language to implement traffic switching and impairments.

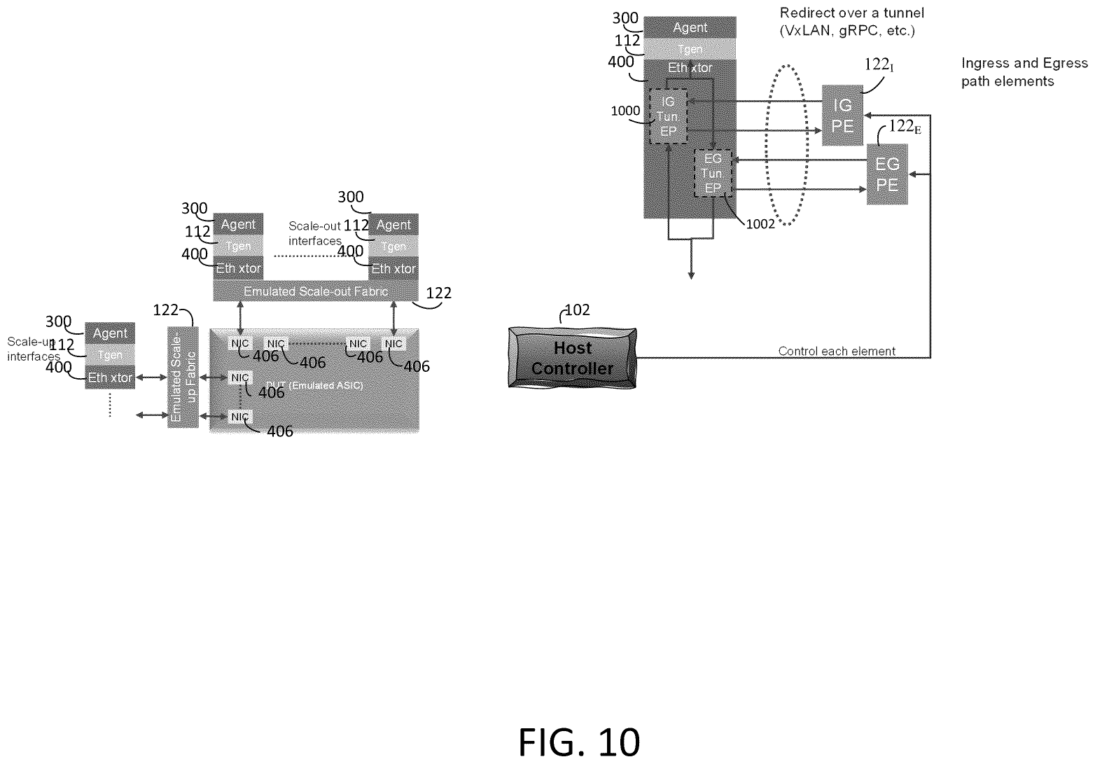

FIG. 10 is a block diagram illustrating the use of tunneling to insert a path emulation element inline between traffic generators and an emulated electronics design under test. In FIG. 10, tunnel endpoints 1000 and 1002 are used to insert an ingress path emulation element 122_{I} and an egress path emulation element 122_{E} between traffic generator 112 and electronics design under test 306. Traffic from traffic generator 112 may be redirected over the tunnel to path emulation element 122_{I}, and path emulation element 122_{I} may perform the switching and impairment functions described herein. Similarly, egress traffic may be directed through path element 122_{E} for similar modifications and switching. The tunnel may be implemented using any suitable tunneling technology, such as virtual extensible local area network (VxLAN), generic routing encapsulation (GRE), or Google remote procedure calls (gRPC) using a streaming RPC. The tunnel may not require a new network device. It could use an existing interface to the transactor, for example, an interface used for a control channel. The tunnel may also be used to send in band control signaling between test system elements.

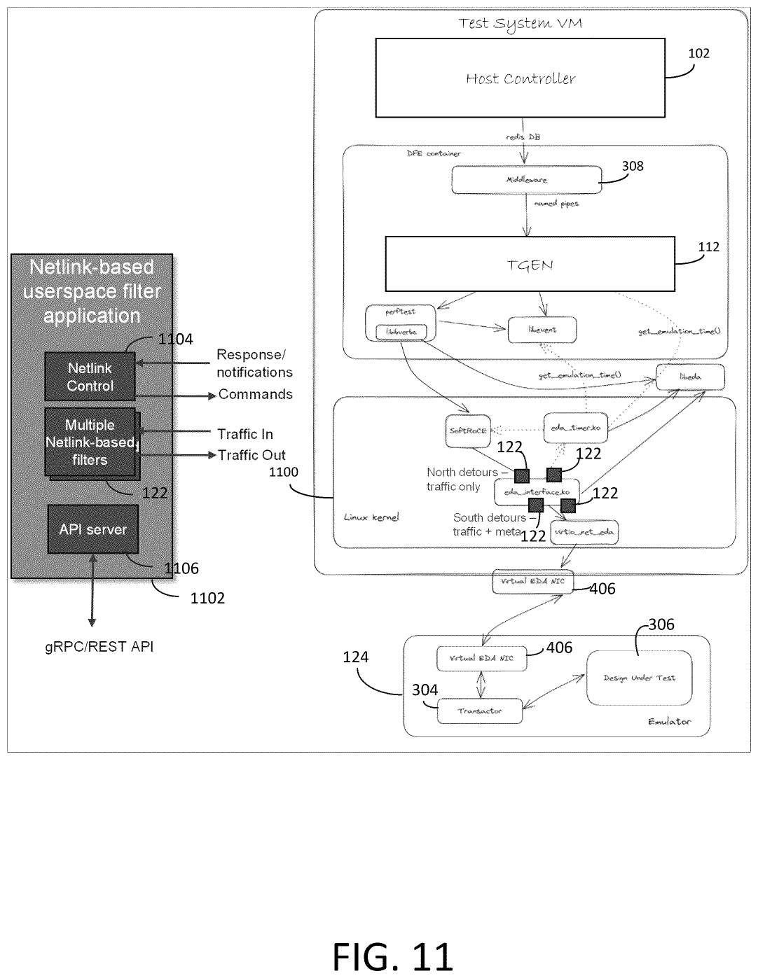

FIG. 11 is a block diagram illustrating the use of Netlink for userspace inline path emulation elements. This technique requires inline path emulation elements to run on the same machine as the EDA kernel modules. Benefits compared to using regular sockets are that we can define an arbitrary Netlink message format which could include metadata and normal traffic data and any other desired EDA-interface-specific information. This technique also provides a convenient inter-process communication (IPC) mechanism to interact with the kernel module. Insertion points for path emulation element 122 can be on the “north” or “south” side of both ingress and egress directions in a kernel module 1100. A userspace application 1102 connects to kernel module 1100 and can register/unregister as inline filter for any or all of the defined points. Without registration, the datapath is direct. With registration, application 1102 “intercepts” the traffic (+metadata) and can modify it, drop it, etc. Arbitrary control/status/notifications can be to application 1102 sent over another Netlink channel implemented by Netlink control component 1104 of application 1102. For example, application 1102 can modify the behavior of the kernel module in real-time; subscribe to the EDA clock updates received from the EDA emulator; etc. Userspace application 1102 also includes an API server 1106 that performs the operations necessary to register application 1102 as an inline filter. A single userspace application should be able to transmit emulated traffic from multiple ports, enumerate them, etc., so the application could emulate a complete switch or even a switch fabric.

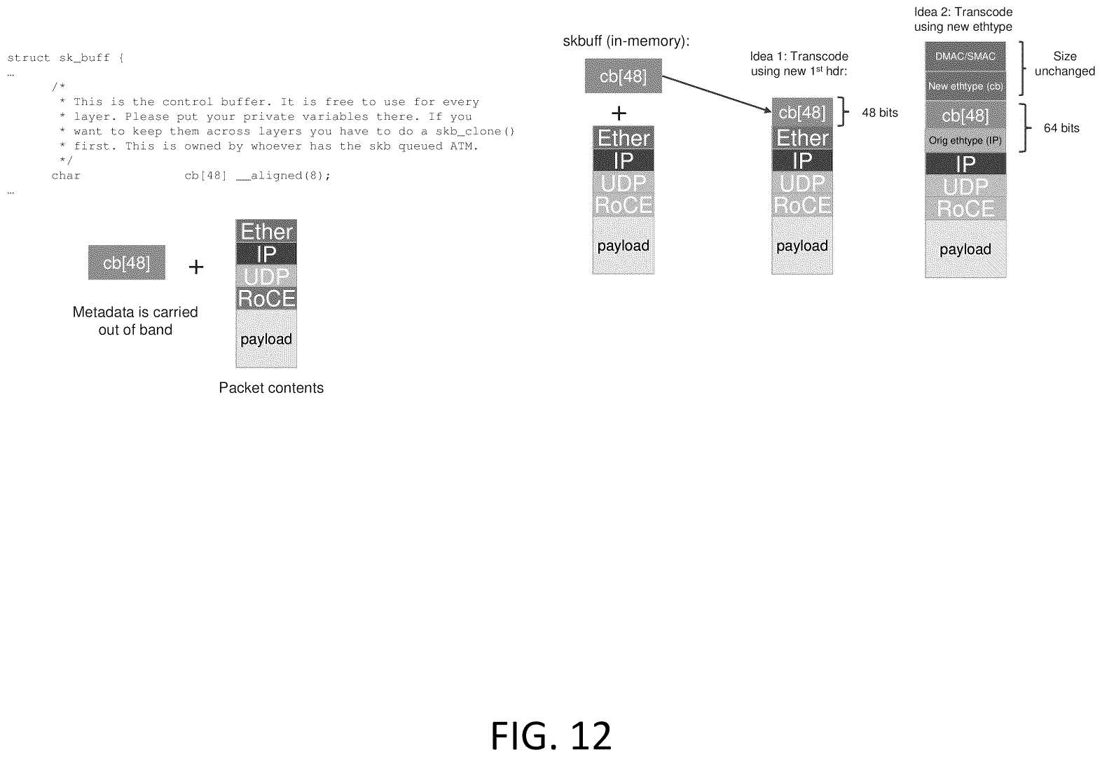

FIG. 12 is a block diagram illustrating methods for communicating emulation metadata as part of a data packet. In one example, the cb[48] opaque user data field (48 user-defined bytes) in the skbuff can be used to communicate emulation metadata out-of-band with the transactor. This is a bespoke interface agreed between test vendors and EDA vendors. This data is carried along with packet contents, inside kernel memory structures in the network stack, and can be used to e.g., signify control data, emulation-clock info, etc. If the test system provides hooks to send data to the path emulation elements via netdev interfaces (e.g., over a socket), the metadata field cannot be carried in the skbuff, because this is in-memory data carried only in the kernel, e.g., it never goes “over the wire.” Instead, the path emulation metadata could be conveyed as a pseudo-header, as illustrated by the packet formats on the right-side of FIG. 12. The pseudo-header can be parsed by path emulation element 122. The pseudo-header can be carried outside of the Ethernet frame, either before or after the Ethernet frame. In one example, the pseudo-header may follow the Ethernet header using a new ethtype (explicit, e.g., like a VLAN tag). In such an implementation, the pseudo-header that holds the metadata may require a 16-bit next header field to preserve original protocol of, for example, the IP layer.

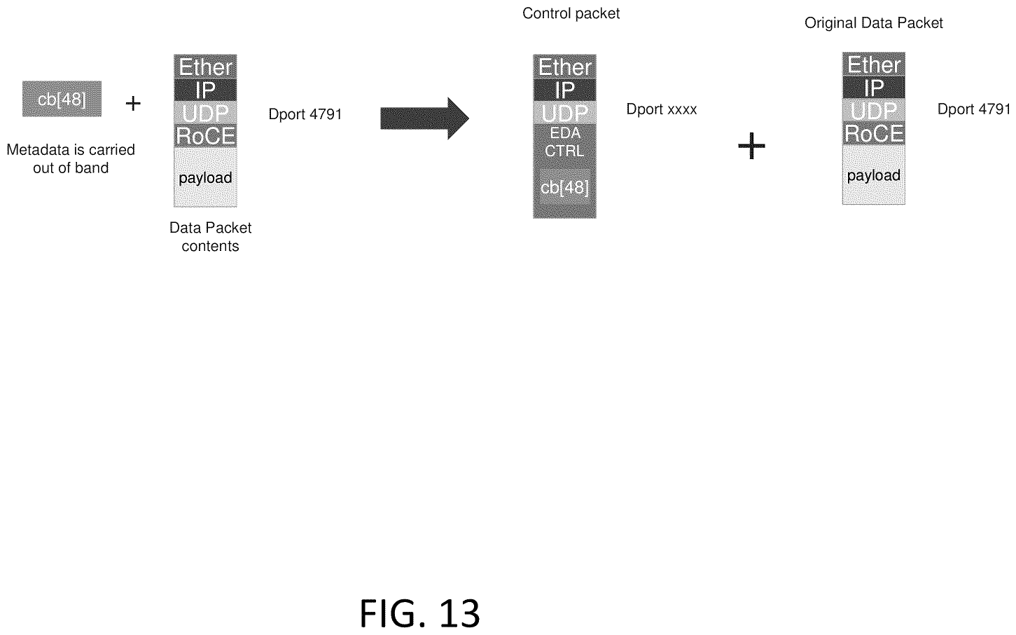

FIG. 13 is a block diagram illustrating methods for communicating emulation metadata as a control packet. As an alternative to appending/inserting metadata in data packet, path emulation element 122 may create a control packet (e.g., a user dataplane protocol (UDP) datagram addressed to a UDP port designated for control packets) containing the impairment and other metadata and send the control packet ahead of the data packet. The timing information (emulation clock, interframe gap, etc.) included in the control packet would apply to the next packet.

One issue with implementing a path emulation element is handling backpresssure when queues or buffers of the electronics design under test become too full to accept more emulated traffic. The indication to the receiving device that the buffers of a receiving device are too full is referred to as backpressure. In testing an EDA design under test, the design under test is the receiving device, and the test traffic generators are the transmitting devices. The indication of backpressure must thus be propagated from the EDA design under test to the traffic generators through the inline path emulation element. FIG. 14 is a block diagram illustrating handling of backpressure when testing an EDA design under test using an inline path emulation element. In FIG. 14, when electronics design under test 306 cannot process incoming packets as fast as the packets are arriving, electronics design under tests 306 may propagate an indication of backpressure to the transactor adapter component of Eth xtor 400. The Eth xtor 400 propagates the indication of backpressure to traffic generator 112 via path emulation element 122 on the traffic generation transmit path. This may be implemented for example as follows: if the transactor adapter and the traffic generator share a virtio buffer (see, e.g., FIG. 7), then the backpressure will be “signaled” by the buffer becoming full at any given time. When the buffer is no longer full, traffic generator 112 detects that the transactor adapter is capable of receiving and thus “backpressure” is released. Path emulation element 112 needs to propagate this backpressure to traffic generator 112. In the virtio case, backpressure propagation occurs naturally (path emulation element 112 cannot send further emulated data packets to the transactor and thus path emulation element 112 will pause). Traffic generator 112 will also pause sending traffic when the virtio buffers are full. As stated above, another issue of communicating emulated data center traffic to an electronics design under test and interpreting results from the electronics design under test is accounting for the differences in timing domains of the test system and the electronics design under test. FIG. 15 is a block diagram illustrating communication of clock information from an EDA emulator to a traffic generator via a path emulation element. The EDA emulator contains the master emulator clock, which is synchronized to events in its gate-level simulation of RTL logic. The emulator sends its clock time to the EDA adapter component of Eth xtor 400 via path emulation element 122 on the traffic generation receive path. Packet “requests” are conveyed from the EDA emulator to traffic generator 112 via path emulation element 122. Traffic generator 112 sends a packet on that port if a packet is deemed to be available according to traffic generator 112, whether this be streaming, event-driven or statefully produced. If/when a packet is available for transmission to the EDA design under test, traffic generator 112 inserts, in the emulated packet to be transmitted, the interframe gap (IFG, e.g. in bytes or some other time quanta) since the last packet, which allows the EDA emulator to modify the reception time accordingly. When packets are sent through path emulation element 122 on the traffic generation receive side, the clock/timing information travels with the packet.

In the EDA-to-xTor direction, clock “control” packets can be sent without data for periodic timekeeping in traffic generator 112 (for stateful timers etc.). Packets going from traffic generator 112 through a path emulation element 122 to the EDA emulator can be dropped/modified etc. Delay is signified by increasing the IFG sent with the packet. For example, if a path emulation element may insert an IFG value in the packet that instructs the transactor to wait a predetermined number of bytes (at the clock rate of the transactor) before delivering the packet to the EDA design under test 306.

Packets going from the EDA design under test 306 through path emulation element 122 cause the path emulation element clock to get updated to emulator time. Delays through path emulation element 122 are signified by advancing the “clock” value included in the packet going to the EDA design under test 306. Clock-only packets going from the EDA design under test 306 to Eth Xtor 400 through a path emulation element chain should update the clock time in each path emulation element 122 be in sync with the EDA emulator. Path emulation elements 122 should forward clock control packets to all destinations. In one example, path emulation elements 122 may multicast the clock control packets to other path emulation elements and to the traffic generators 112.

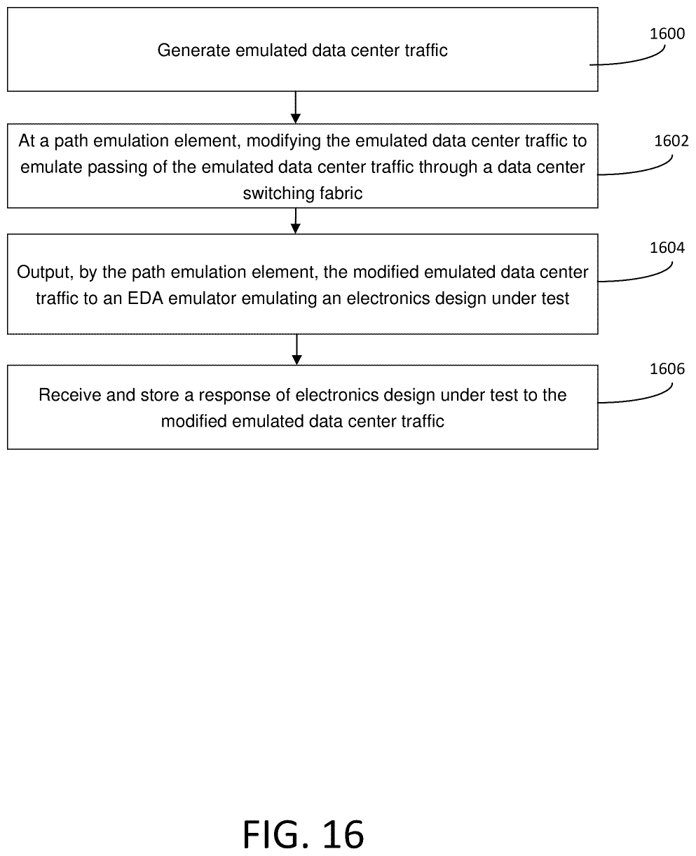

Referring to FIG. 16, in step 1600, the process generating emulated data center traffic. For example, agents 300 emulating GPUs may produce emulated AI/ML workload data. Traffic generators 112 may packetize the data packets in Ethernet frames.

In step 1602, the process includes at a path emulation element, modifying the emulated data center traffic to emulate passing of the emulated data center traffic through a data center switching fabric. For example, path emulation elements 122 may intercept, impair, and switch the emulated data center traffic generated by traffic generators 112.

In step 1604, the process further includes outputting, by the path emulation element, the modified emulated data center traffic to an EDA emulator emulating an electronics design under test. For example, path emulation element 122 may output the emulated data center traffic to EDA emulator 124, which provides the traffic to the emulated electronics design under test.

In step 1606, the process further includes receiving and storing a response of electronics design under test to the modified emulated data center traffic. For example, test system 100 may receive and store emulated data center traffic after being switched or otherwise processed by the electronics design under test.

It will be understood that various details of the subject matter described herein may be changed without departing from the scope of the subject matter described herein. Furthermore, the foregoing description is for the purpose of illustration only, and not for the purpose of limitation, as the subject matter described herein is defined by the claims as set forth hereinafter.

What is claimed is:

1. A method for data center switching fabric path emulation in an electronics design automation (EDA) environment, the method comprising:
generating emulated data center traffic;
at a path emulation element, modifying the emulated data center traffic to emulate passing of the emulated data center traffic through a data center switching fabric;
outputting, by the path emulation element, the modified emulated data center traffic to an EDA emulator emulating an electronics design under test; and
receiving and storing a response of electronics design under test to the modified emulated data center traffic.

2. The method of claim 1 wherein generating emulated data center traffic includes generating emulated traffic of a data center processing an artificial intelligence/machine learning (AI/ML) workload.

3. The method of claim 1 modifying the emulated data center traffic includes adding, to the emulated data center traffic, a packet timing parameter that controls a time at which a transactor of the EDA emulator provides an emulated data packet to the electronics design under test.

4. The method of claim 1 wherein the path emulation element is implemented as an inline device between a test traffic generator that generates the emulated data center traffic and the EDA emulator.

5. The method of claim 4 wherein the path emulation element is connected between virtual interfaces between the test traffic generator and the EDA emulator.

6. The method of claim 5 wherein the path emulation element is implemented using a network device (netdev), an emulated switch, or a filter connected between the virtual interfaces.

7. The method of claim 4 wherein the path emulation element is located in a tunnel between the test traffic generator and the EDA emulator.

8. The method of claim 4 wherein the path emulation element is configured to propagate indications of backpressure and communicate emulator timing information from the EDA emulator to the test traffic generator.

9. The method of claim 1 wherein the path emulation element is integrated within a test traffic generator that generates the emulated data center traffic.

10. The method of claim 1 wherein the path emulation element is implemented as a component of a transactor of the EDA emulator.

11. A system for data center switching fabric path emulation in an electronics design automation (EDA) environment, the system comprising:
at least one processor and a memory;
a test traffic generator for generating emulated data center traffic;
a path emulation element implemented by the at least one processor for modifying the emulated data center traffic to emulate passing of the emulated data center traffic through a data center switching fabric and outputting the modified emulated data center traffic to an EDA emulator emulating an electronics design under test; and
a test results database receiving and storing a response of electronics design under test to the modified emulated data center traffic.

12. The system of claim 11 wherein the test traffic generator is configured to generate emulated traffic of a data center processing an artificial intelligence/machine learning (AI/ML) workload.

13. The system of claim 11 wherein the path emulation element is configured to modify the emulated data center traffic by adding, to the emulated data center traffic, a packet timing parameter that controls a time at which a transactor of the EDA emulator provides an emulated data packet to the electronics design under test.

14. The system of claim 11 wherein the path emulation element is implemented as an inline device between a test traffic generator that generates the emulated data center traffic and the EDA emulator.

15. The system of claim 14 wherein the path emulation element is connected between virtual interfaces between the test traffic generator and the EDA emulator.

16. The system of claim 15 wherein the path emulation element is implemented using a network device (netdev), an emulated switch, or a filter connected between the virtual interfaces.

17. The system of claim 14 wherein the path emulation element is located in a tunnel between the test traffic generator and the EDA emulator.

18. The system of claim 14 wherein the path emulation element is configured to propagate indications of backpressure and communicate emulator timing information from the EDA emulator to the test traffic generator.

19. The system of claim 11 wherein the path emulation element is implemented as a component of a transactor of the EDA emulator.

20. A non-transitory computer readable medium having stored thereon executable instructions that when executed by a processor of a computer control the computer to perform steps comprising:
generating emulated data center traffic;
at a path emulation element, modifying the emulated data center traffic to emulate passing of the emulated data center traffic through a data center switching fabric;
outputting, by the path emulation element, the modified emulated data center traffic to an electronics design automation (EDA) emulator emulating an electronics design under test; and
receiving and storing a response of electronics design under test to the modified emulated data center traffic.
